(19) United States
(12) Patent Application Publication
(10) Pub. No.: US 2011/0042794 A1
(43) Pub. Date: Feb. 24, 2011

(54) QFN SEMICONDUCTOR PACKAGE AND CIRCUIT BOARD STRUCTURE ADAPTED FOR THE SAME

(76) Inventors: Tung-Hsien Hsieh, Changhua County (TW); Nan-Cheng Chen, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/938,390

(22) Filed: Nov. 3, 2010

Related U.S. Application Data
(63) Continuation-in-part of application No. 12/840,304, filed on Jul. 21, 2010.
Application No. 12/840,304 is a continuation of application No. 12/390,492, filed on Feb. 22, 2009, now Pat. No. 7,786,557.
(60) Provisional application No. 61/054,172, filed on May 19, 2008.

(51) Int. Cl. H01L 23/48

(52) U.S. Cl. 257/676; 257/E23.01

(57) ABSTRACT

A QFN package includes a die attach pad having a recessed area; a semiconductor die mounted inside the recessed area; an inner terminal lead disposed adjacent to the die attach pad; a first wire bonding the inner terminal lead to the semiconductor die; an outer terminal lead; an intermediary terminal disposed between the inner terminal lead and the outer terminal lead; a second wire bonding the intermediary terminal to the semiconductor die; and a third wire bonding the intermediary terminal to the outer terminal lead. A circuit board includes a core layer; a first metal trace disposed over a first side of the core layer; and a first solder mask covering the first metal trace. The QFN package is mounted over the first solder mask. No metal pad of the first metal trace is formed within an area corresponding to the intermediary terminal.

### CROSS REFERENCE TO RELATED APPLICATIONS

This is a continuation-in-part of U.S. application Ser. No. 12/840,304 filed on Jul. 21, 2010, which itself is a continuation of U.S. application Ser. No. 12/390,492 filed on Feb. 22, 2009, which claims the benefit of U.S. provisional application No. 61/054,172 filed on May 19, 2008, hereby all incorporated by references.

### BACKGROUND OF THE INVENTION

1. Field of the Invention

The present invention relates generally to the field of chip packaging and, more particularly, to a high-pin-count quad flat non-leaded (QFN) semiconductor package having extended terminal leads and fabrication method thereof.

2. Description of the Prior Art

The handheld consumer market is aggressive in the miniaturization of electronic products. Driven primarily by the cellular phone and digital assistant markets, manufacturers of these devices are challenged by ever shrinking formats and the demand for more PC-like functionality. Additional functionality can only be achieved with higher performing logic IC's accompanied by increased memory capability. This challenge, combined together in a smaller PC board format, asserts pressure on surface mount component manufactures to design their products to command the smallest area possible.

Many of the components used extensively in today's handheld market are beginning to migrate from traditional leaded frame designs to non-leaded formats. The primary driver for handheld manufacturers is the saved PC board space created by these components' smaller mounting areas. In addition, most components also have reductions in weight and height, as well as an improved electrical performance. As critical chip scale packages are converted to non-leaded designs, the additional space saved can be allocated to new components for added device functionality. Since non-leaded designs can use many existing leadframe processes, costs to convert a production line can be minimized.

Similar to leaded components, nonleaded designs use wire bond as the primary interconnection between the IC and the frame. However, due to the unique land site geometry and form factor density, traditional wire bond processes may not produce high yielding production. For these designs, additional wire bond capabilities and alternate processes are needed to produce acceptable production yields.

U.S. Pat. No. 6,238,952 discloses a low-pin-count chip package including a die pad for receiving a semiconductor chip and a plurality of connection pads electrically coupled to the semiconductor chip wherein the die pad and the connection pads have a concave profile. A package body is formed over the semiconductor chip, the die pad and the connection pads in a manner that a potion of the die pad and a portion of each connection pad extend outward from the bottom of the package body.

U.S. Pat. No. 6,261,864 discloses a chip package. The semiconductor chip, the die pad, and the connection pads are encapsulated in a package body such that the lower surfaces of the die pad and the connection pads are exposed through the package body. The die pad and the connection pads are formed by etching such that they have a concave profile and a thickness far larger than that of conventional die pad and connection pads formed by plating.

U.S. Pat. No. 6,306,685 discloses a method of molding a bump chip carrier. Dry films are applied to the top and bottom surface of a copper base plate having a suitable thickness. A circuit pattern is formed on each one of the dry films. Metals are plated onto each of the circuit patterns to form connection pads and an exothermic passage. A die is mounted on the copper base plate. The surfaces of the copper base plate on which the die is mounted are molded to form a molding layer.

U.S. Pat. No. 6,342,730 discloses a package structure including a die pad for receiving a semiconductor chip and a plurality of connection pads electrically coupled to the semiconductor chip. The semiconductor chip, the die pad, and the connection pads are encapsulated in a package body such that the lower surfaces of the die pad and the connection pads are exposed through the package body. The die pad and the connection pads have a substantially concave profile.

U.S. Pat. No. 6,495,909 discloses a chip package. The semiconductor chip, the die pad, and the connection pads are encapsulated by a package body in a manner that the lower surfaces of the die pad and the connection pads are exposed through the package body. The die pad and the connection pads have a T-shaped profile thereby prolonging the time for moisture diffusion into the package.

U.S. Pat. No. 6,621,140 discloses a semiconductor package with inductive segments integrally formed in the leadframe. The inductive segments may be connected directly to a lead of the leadframe, or indirectly to a lead or a bond pad on a semiconductor die via wirebonds to form an inductor.

### SUMMARY OF THE INVENTION

It is one objective to provide a high-pin-count quad flat non-leaded (QFN) semiconductor package having extended terminal leads and fabrication method thereof.

It is another objective of the invention to provide an improved circuit board or PCB that is adapted for the QFN semiconductor package of the invention.

According to one embodiment of the invention, a circuit board adapted for a QFN semiconductor package is provided. The QFN semiconductor package comprises a die attach pad having a recessed area; a semiconductor die mounted inside the recessed area; at least one inner terminal lead disposed adjacent to the die attach pad; a first wire bonding the inner terminal lead to the semiconductor die; at least one outer terminal lead; at least one intermediary terminal disposed between the inner terminal lead and the outer terminal lead; a second wire bonding the at least one intermediary terminals to the semiconductor die; and a third wire bonding the at least one intermediary terminal to the outer terminal lead. The circuit board comprises a core layer having a first side and a second side opposite to the first side; a first metal trace disposed over the first side of the core layer; a first solder mask covering the first metal trace, wherein said QFN semiconductor package is mounted over the first solder mask; wherein no metal pad of the first metal trace is formed within an area corresponding to the at least one intermediary terminal.

According to another embodiment of the invention, a circuit board adapted for a QFN semiconductor package is provided. The QFN semiconductor package comprising a die attach pad having a recessed area; a semiconductor die mounted inside the recessed area; at least one inner terminal lead disposed adjacent to the die attach pad; a first wire bonding the inner terminal lead to the semiconductor die; at least one outer terminal lead; at least one intermediary terminal disposed between the inner terminal lead and the outer terminal lead; a second wire bonding the at least one intermediary terminal to the semiconductor die; and a third wire bonding the at least one intermediary terminal to the outer terminal lead. The circuit board comprises a core layer having a first side and a second side opposite to the first side; a first metal trace disposed over the first side of the core layer; a first solder mask covering the first metal trace, wherein said QFN semiconductor package is mounted over the first solder mask; and a metal pad of the first metal trace within an area corresponding to the at least one intermediary terminal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram illustrating a quad flat non-lead (QFN) semiconductor package with intermediary terminals in accordance with one embodiment of this invention.

FIG. 2 is a top view of the exemplary layout of the QFN semiconductor package with intermediary terminals in accordance with the embodiment of this invention.

FIG. 3 is a schematic, enlarged top view showing the interconnection between the outer terminal leads and the intermediary terminals in accordance with another embodiment of this invention.

FIG. 4 to FIG. 11 are schematic, cross-sectional diagrams showing an exemplary method for making the QFN semiconductor package of FIG. 1.

FIG. 12 is a schematic, cross-sectional diagram illustrating a QFN semiconductor package with intermediary terminals in accordance with still another embodiment of this invention.

FIG. 13 is a schematic, cross-sectional diagram illustrating a circuit board structure adapted for the novel QFN semiconductor package with intermediary terminals in accordance with another aspect of this invention.

FIG. 14 is a schematic, cross-sectional diagram illustrating a circuit board structure adapted for the novel QFN semiconductor package with intermediary terminals in accordance with still another aspect of this invention.

FIG. 15 is a schematic, cross-sectional diagram illustrating a circuit board structure adapted for the novel QFN semiconductor package with intermediary terminals in accordance with still another aspect of this invention.

FIG. 16 is a schematic, cross-sectional diagram illustrating a circuit board structure adapted for the novel QFN semiconductor package with intermediary terminals in accordance with still another aspect of this invention.

FIG. 17 is a schematic, cross-sectional diagram illustrating a circuit board structure adapted for the novel QFN semiconductor package with intermediary terminals in accordance with still another aspect of this invention.

FIG. 18 is a schematic, cross-sectional diagram illustrating a QFN semiconductor package with intermediary terminals in accordance with yet another embodiment of this invention.

### DETAILED DESCRIPTION

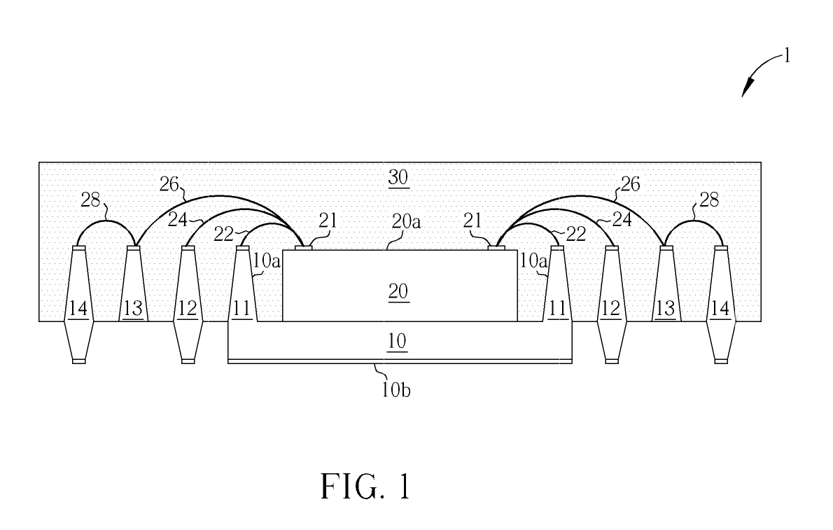

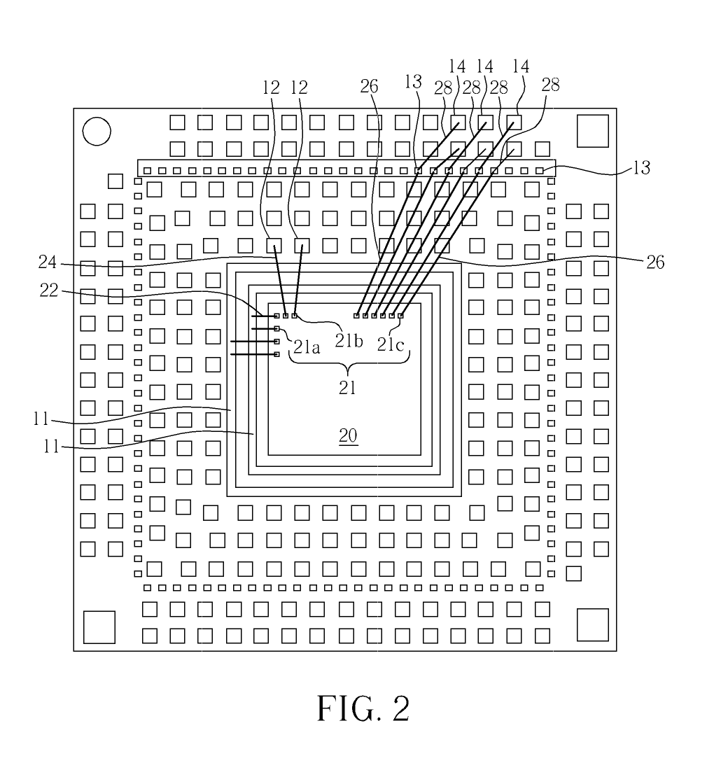

Please refer to FIG. 1 and FIG. 2. FIG. 1 is a schematic, cross-sectional diagram illustrating a quad flat non-lead (QFN) semiconductor package with intermediary terminals in accordance with one embodiment of this invention. FIG. 2 is a top view of the exemplary layout of the QFN semiconductor package with intermediary terminals in accordance with the embodiment of this invention. As shown in FIG. 1 and FIG. 2, the QFN semiconductor package 1 includes a die attach pad 10 having a recessed area 10a. A semiconductor die 20 is mounted inside the recessed area 10a of the die attach pad 10. The die attach pad 10 has a bottom surface 10b that is exposed within the mold cap 30. The die attach pad 10 may comprises a power or ground ring 11. At least one row of inner terminal leads 12 is disposed adjacent to the die attach pad 10. At least one row of extended, outer terminal leads 14 is disposed along the periphery of the QFN semiconductor package 1. At least one row of intermediary terminals 13 is disposed between the inner terminal leads 12 and the extended, outer terminal leads 14. According to another embodiment of this invention, the die attach pad 10 may be omitted.

The semiconductor die 20 has a top surface 20a with a plurality of bonding pads 21 including bonding pads 21a, 21b and 21c. The bonding pads 21a on the semiconductor die 20 are wire bonded to the power or ground ring 11 through the gold wires 22. The bonding pads 21b on the semiconductor die 20 are wire bonded to the inner terminal leads 12 through the gold wires 24. The bonding pads 21c on the semiconductor die 20 are wire bonded to the intermediary terminals 13 through the gold wires 26.

According to this embodiment, the outer terminal leads 14 are disposed beyond the maximum wire length that a wire bonding tool or wire bonder can provide for a specific minimum pad opening size. It is known that the maximum wire length that a wire bonder can provide depends upon the minimum pad opening size of the bonding pads on the die.

For example, for the bonding pads 21 having a minimum pad opening size of 43 micrometers, a typical wire bonder can only provide a maximum wire length of 140 mils (3556 micrometers). According to the exemplary embodiment of this invention, the gold wires 26 have the maximum wire length that a wire bonding tool or wire bonder can provide for a specific minimum pad opening size. In order to electrically interconnect the bonding pads 21c with the outer terminal leads 14, the intermediary terminals 13 are wire bonded to the corresponding outer terminal leads 14 through gold wires 28.

It is understood that the arrangement or layout of the single row of the intermediary terminals 13 is merely exemplary and should not be used to limit the scope of this invention. In another case, the intermediary terminals 13 may be arranged in two or more rows, or may be arranged alternately in two rows. According to this embodiment, each of the intermediary terminals 13 could occupy a smaller bonding surface area than each of the outer terminal leads 14 that has a bonding surface area substantially equal to each of the inner terminal leads 12.

The smaller intermediary terminals 13 are best seen in FIG. 2. For example, each of the inner terminal leads 12 and the outer terminal leads 14 has a dimension of 270 μm×270 μm, and each of the intermediary terminals 13 has a dimension of 150 μm×150 μm. It is to be understood that the bonding surface area of each of the intermediary terminals 13 must be adequate to accommodate two squash balls (not explicitly shown) of the two gold wires 26 and 28.

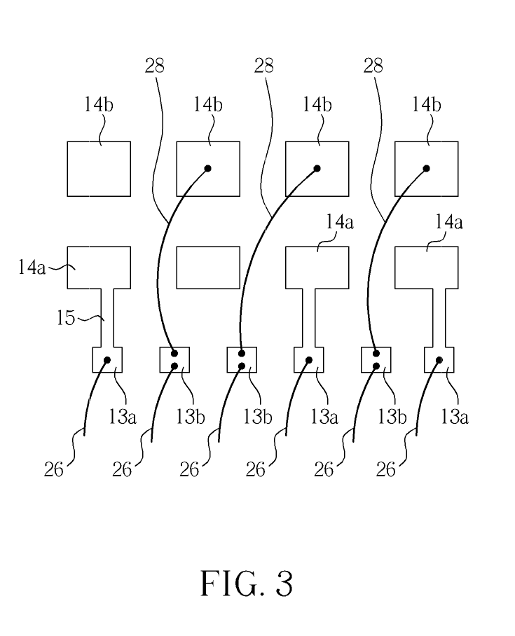

FIG. 3 is a schematic, enlarged top view showing the interconnection between the outer terminal leads and the intermediary terminals in accordance with another embodiment of this invention. As shown in FIG. 3, the outer terminal lead 14a in a first row is electrically interconnected to the intermediary terminal 13a through a trace 15, while the outer terminal lead 14b in a farther second row is electrically interconnected to the intermediary terminal 13a through the gold wire 28.

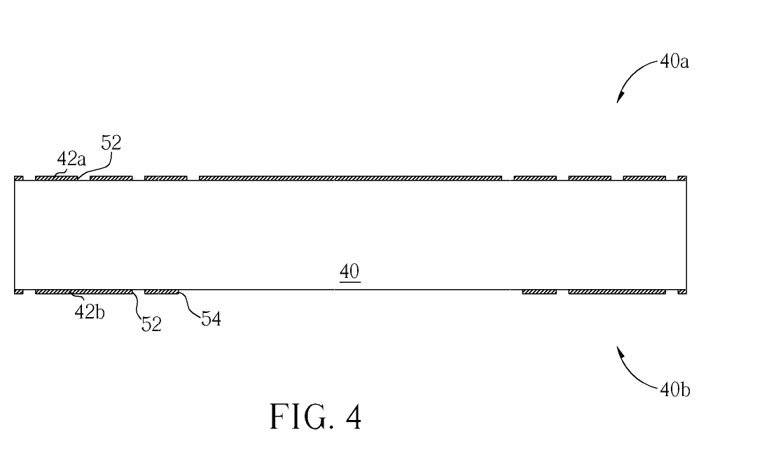

FIG. 4 to FIG. 11 are schematic, cross-sectional diagrams showing an exemplary method for making the QFN semiconductor package 1 with intermediary terminals of FIG. 1, wherein like numeral numbers designate like regions, layers or elements. As shown in FIG. 4, a copper carrier 40 is provided. A patterned photoresist film 42a and a patterned photoresist film 42b are formed respectively on the opposite first and second sides 40a and 40b of the copper carrier 40 for defining lead array patterns 52 and a die attach pad pattern 54 thereon.

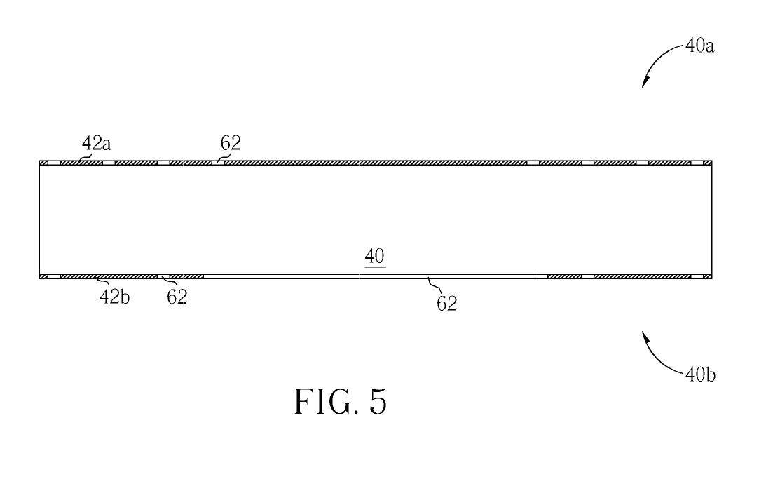

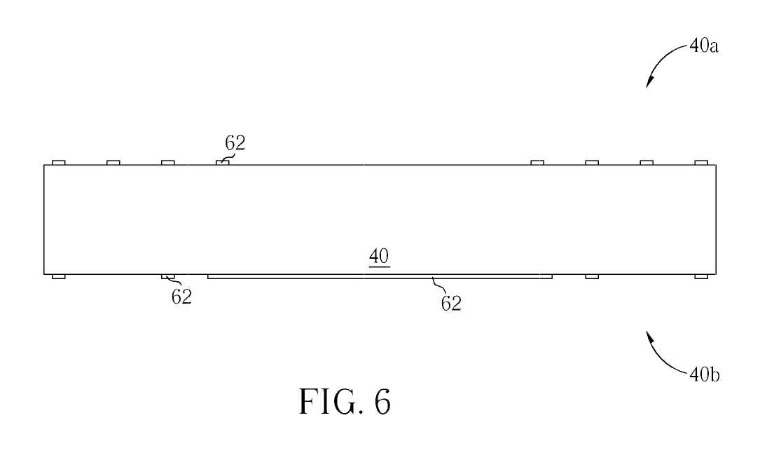

As shown in FIG. 5, a plating process is carried out to fill the lead array patterns 52 and the die attach pad pattern 54 on the two opposite sides of the copper carrier 40 with a bondable metal layer 62 such as nickel, gold or combination thereof. As shown in FIG. 6, the patterned photoresist film 42a and the patterned photoresist film 42b are stripped off to expose a portion of the surface of the copper carrier 40.

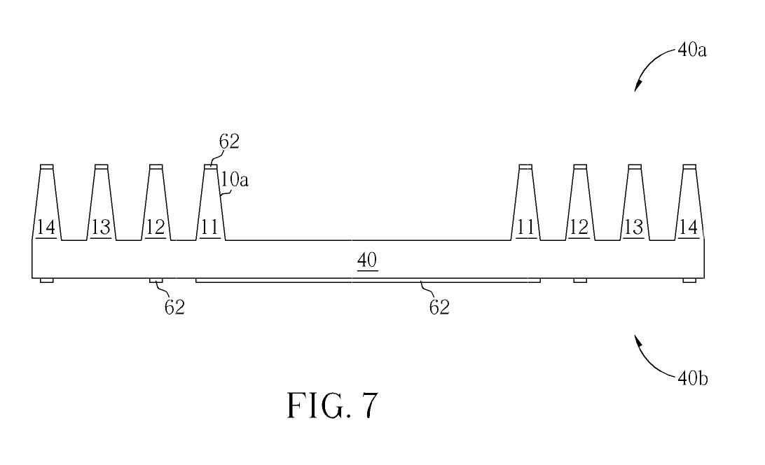

As shown in FIG. 7, subsequently, a copper etching process is performed to half etch the exposed portion of the copper carrier 40 from the first side 40a. A recessed area 10a is formed on the first side 40a. During the copper etching process, the bondable metal layer 62 acts as an etching hard mask. According to this embodiment, the steps described through FIG. 4 to FIG. 7 may be performed in a leadframe manufacturing factory.

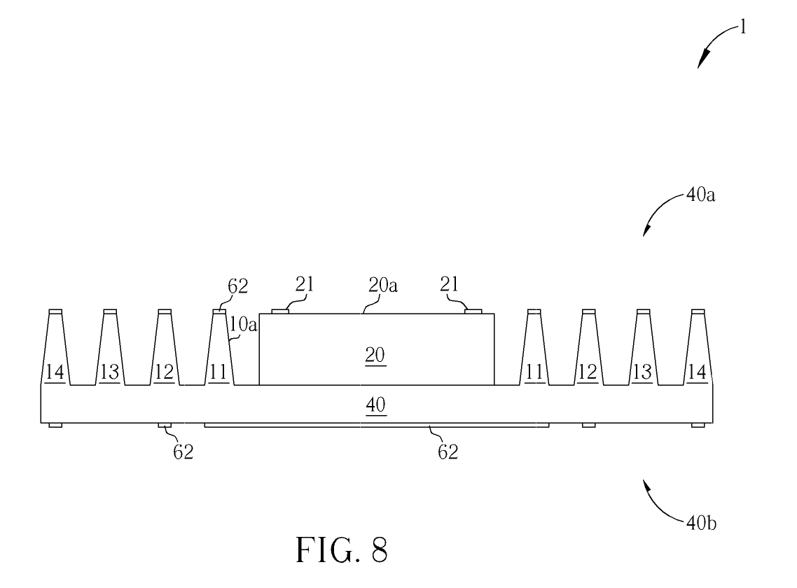

As shown in FIG. 8, a semiconductor die 20 is mounted inside the recessed area 10a, for example, by surface mount technology (SMT) or any other suitable methods. The semiconductor die 20 has a top surface 20a with a plurality of bonding pads, which are not explicitly shown.

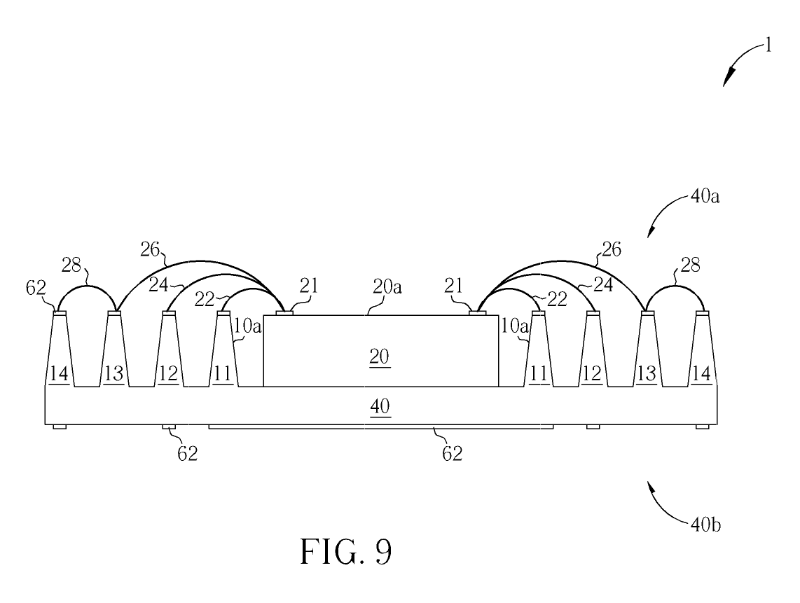

As shown in FIG. 9, a wire bonding process is carried out to electrically interconnect the bonding pads on the top surface 20a of the semiconductor die 20 with the corresponding terminal leads through gold wires 22, 24, 26 and 28 respectively. As previously mentioned, the maximum wire length that a wire bonder can provide in the wire bonding process depends upon the minimum pad opening size of the bonding pads on the semiconductor die 20. For example, for the bonding pads having minimum pad opening size of 43 micrometers, a typical wire bonder can only provide a maximum wire length of 140 mils (3556 micrometers). According to this embodiment, the gold wires 26 have the maximum wire length that a wire bonding tool or wire bonder can provide for a specific minimum pad opening size.

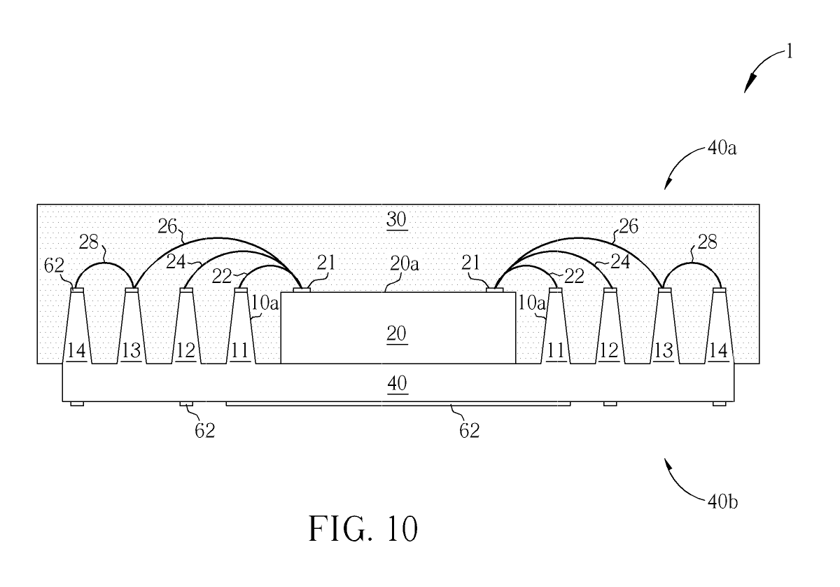

As shown in FIG. 10, a molding process is performed. The semiconductor die 20, gold wires 22, 24, 26 and 28, and the first side 40a of the copper carrier 40 is encapsulated within a mold cap 30 such as epoxy resins.

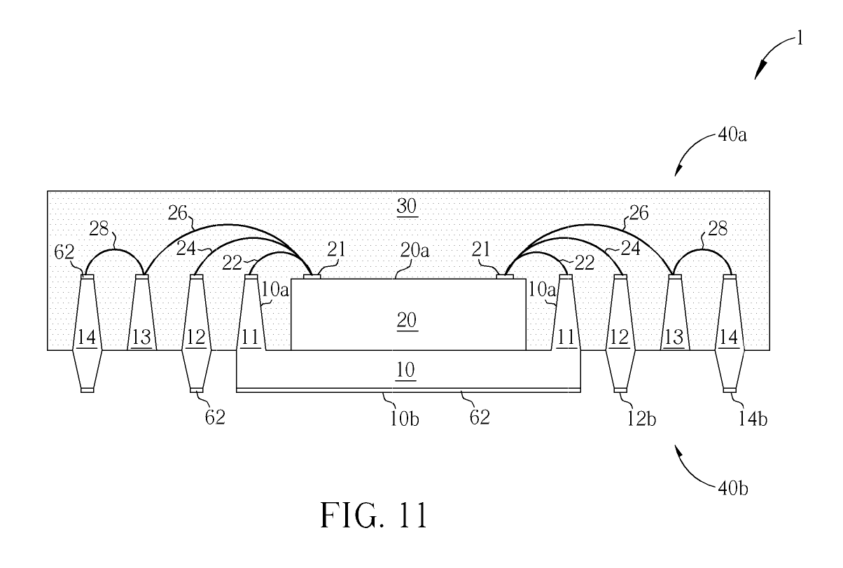

As shown in FIG. 11, after the molding process, a copper etching process is performed to half etch the exposed copper carrier 40 that is not covered by the bondable metal layer 62 from the second side 40b, thereby forming die attach pad 10, power or ground ring 11, inner terminal leads 12, intermediary terminals 13 and the outer terminal leads 14. According to this embodiment, the power or ground ring 11 is integrally formed with the die attach pad 10 and is annular-shaped. The power or ground ring 11 may be continuous or discontinuous. The die attach pad 10, the inner terminal leads 12 and the outer terminal leads 14 have exposed bottom surfaces 10b, 12b and 14b respectively, which are substantially coplanar. The exposed bottom surfaces 10b, 12b and 14b of the die attach pad 10, the inner terminal leads 12 and the outer terminal leads 14 respectively are eventually bonded to a printed circuit board. The intermediary terminal 13 has a recessed bottom surface 13b that is not coplanar with any of the exposed bottom surfaces 10b, 12b and 14b. According to this embodiment, the steps described through FIG. 8 to FIG. 11 may be performed in an assembly or packaging house.

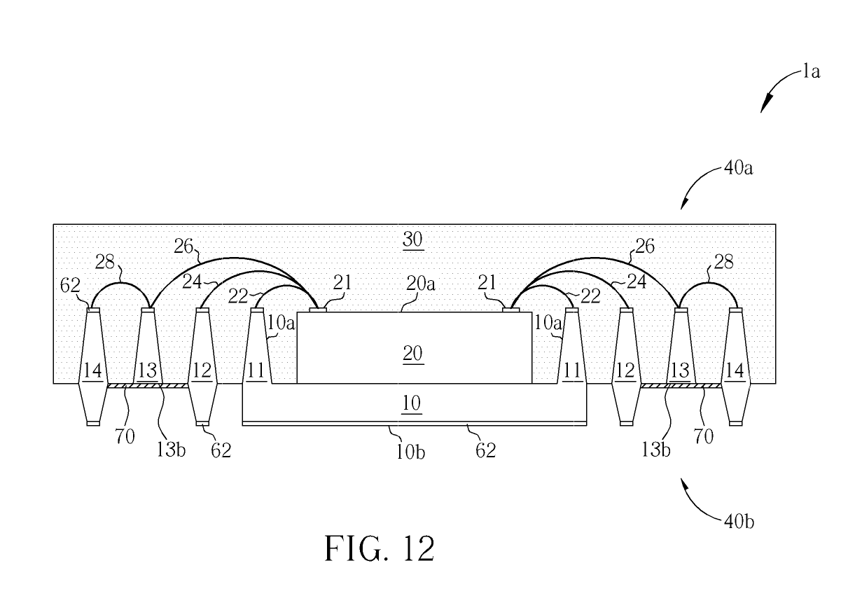

FIG. 12 is a schematic, cross-sectional diagram illustrating a QFN semiconductor package with intermediary terminals in accordance with still another embodiment of this invention. As shown in FIG. 12, the difference between the QFN semiconductor package 1 of FIG. 1 and the QFN semiconductor package 1a of FIG. 12 is that in FIG. 12 the bottom surface 13b of the intermediary terminal 13 is covered with a protection layer 70 such as glue or any suitable insulating materials for avoiding shorting with the printed circuit board.

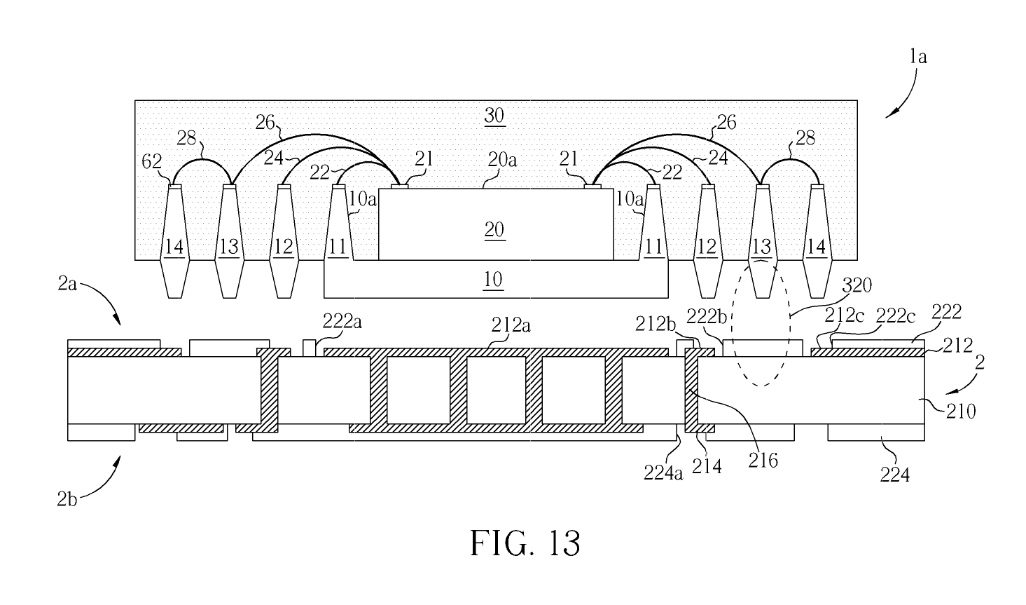

FIG. 13 is a schematic, cross-sectional diagram illustrating a circuit board structure adapted for the novel QFN semiconductor package with intermediary terminals in accordance with another aspect of this invention. As shown in FIG. 13, the QFN semiconductor package 1a is substantially identical to the structure as shown in FIG. 11 except for that the bottom of at least one of the intermediary terminals 13 of the QFN semiconductor package 1a is not etched away. That is, the intermediary terminal 13 of the QFN semiconductor package 1a protrudes from a bottom surface of the mold cap 30. The circuit board 2 for the QFN semiconductor package 1a may comprise a core layer 210, a first metal trace 212 disposed on a package assembling side 2a of the circuit board 2, a second metal trace 214 disposed on a bottom side 2b of the circuit board 2, a first solder mask 222 covering the first metal trace 212, a second solder mask 224 covering the second metal trace 214. The first metal trace 212 may be electrically connected with the second metal trace 214 by means of the plated through hole 216. The first solder mask 222 has at least openings 222a, 222b and 222c that expose bond pads 212a, 212b and 212c respectively. The bond pads 212a, 212b and 212c correspond to the die attach pad 10, the inner terminal lead 12 and the outer terminal lead 14 respectively. According to this embodiment, no opening and no metal pad are formed in the first solder mask 222 within the area 320 corresponding to the intermediary terminal 13. When assembling, the QFN semiconductor package 1a is mounted on the package assembling side 2a of the circuit board 2. More specifically, the QFN semiconductor package 1a is mounted over the first solder mask 222. The die attach pad 10 directly contacts the bond pad 212a. The inner terminal lead 12 directly contacts the bond pad 212b. The outer terminal lead 14 directly contacts the bond pad 212c. The intermediary terminal 13 directly contacts the first solder mask 222 and may be inlaid into the first solder mask 222. The aforesaid “no opening/no metal pad” requirement may be applicable to one of the intermediary terminals 13 of the QFN semiconductor package 1a. However, it is understood that the aforesaid “no opening/no metal pad” requirement may be applicable to at least one or even all of the intermediary terminals 13 of the QFN semiconductor package 1a.

It is to be understood that the circuit boards having two levels of metal traces as depicted through FIGS. 13-17 are for illustration purposes only. For example, the circuit board may comprise multiple levels such as six, eight or ten levels of metal traces on two opposite sides of the core layer in other cases. It is also to be understood that when a layer is referred to as being “on” or “over” another layer or substrate, it can be directly on the other layer or substrate, or intervening layers may also be present.

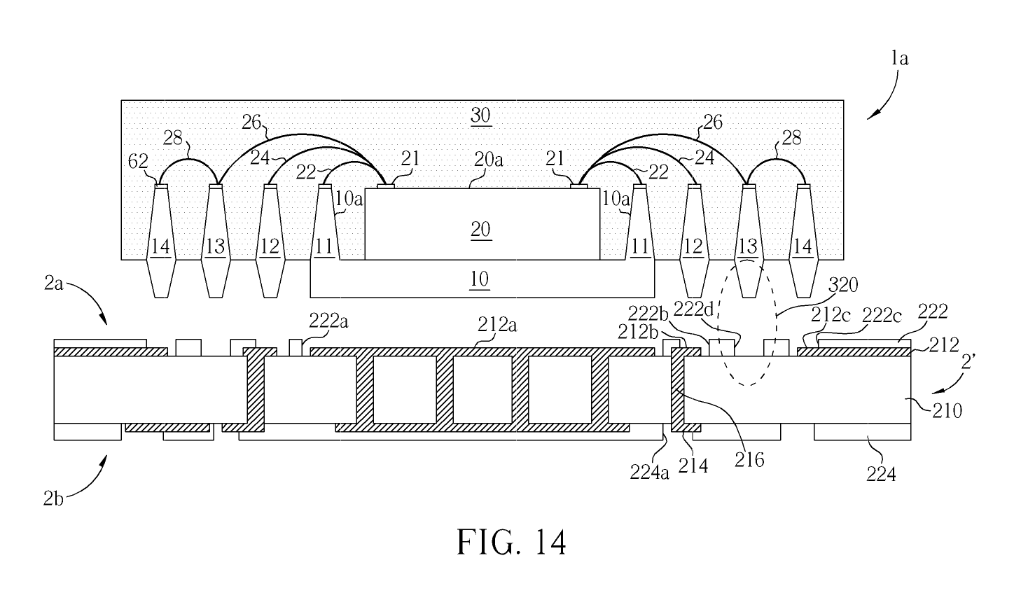

FIG. 14 is a schematic, cross-sectional diagram illustrating a circuit board structure adapted for the novel QFN semiconductor package with intermediary terminals in accordance with still another aspect of this invention. As shown in FIG. 14, the QFN semiconductor package 1a is identical to the structure as shown in FIG. 13. The bottom of at least one of the intermediary terminals 13 of the QFN semiconductor package 1a is not etched away. That is, the intermediary terminal 13 of the QFN semiconductor package 1a protrudes from a bottom surface of the mold cap 30. Likewise, the circuit board 2′ adapted for the QFN semiconductor package 1a may comprise a core layer 210, a first metal trace 212 disposed on a package assembling side 2a of the circuit board 2, a second metal trace 214 disposed on a bottom side 2b of the circuit board 2, a first solder mask 222 covering the first metal trace 212, a second solder mask 224 covering the second metal trace 214. The first metal trace 212 may be electrically connected the second metal trace 214 by means of the plated through hole 216. The first solder mask 222 has at least openings 222a, 222b and 222c that expose bond pads 212a, 212b and 212c respectively. The first solder mask 222 further has at least an opening 222d corresponding to the intermediary terminal 13 within the area 320. The bond pads 212a, 212b and 212c correspond to the die attach pad 10, the inner terminal lead 12 and the outer terminal lead 14 respectively. According to this embodiment, no metal pad is formed in the first solder mask 222 within the area 320 corresponding to the intermediary terminal 13. When assembling, the QFN semiconductor package 1a is mounted on the package assembling side 2a of the circuit board 2′. The die attach pad 10 directly contacts the bond pad 212a. The inner terminal lead 12 directly contacts the bond pad 212b. The outer terminal lead 14 directly contacts the bond pad 212c. The intermediary terminal 13 may directly contact the core layer 210 and may be inlaid into the opening 222d.

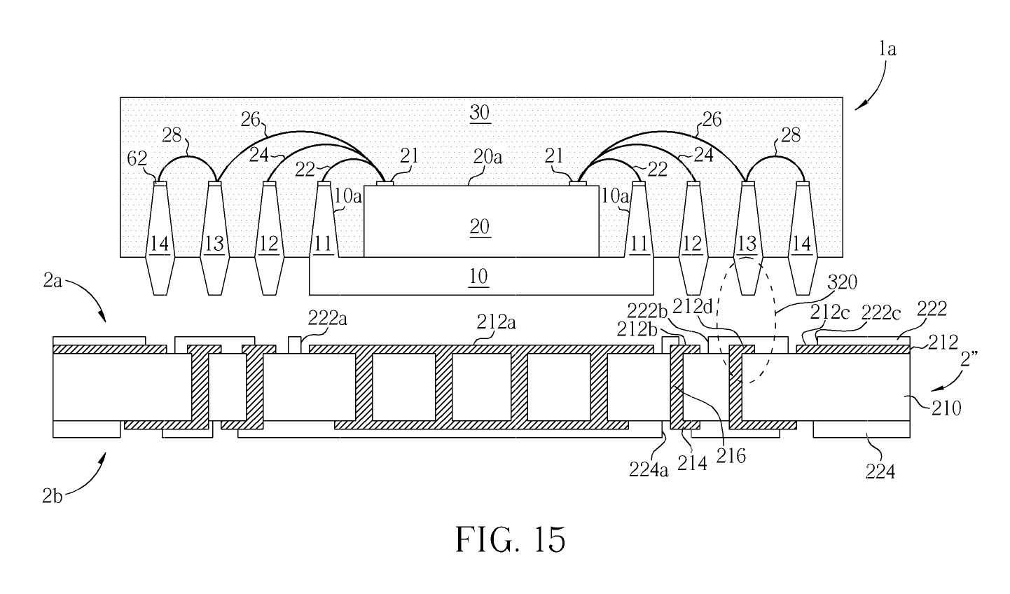

FIG. 15 is a schematic, cross-sectional diagram illustrating a circuit board structure adapted for the novel QFN semiconductor package with intermediary terminals in accordance with still another aspect of this invention. As shown in FIG. 15, the QFN semiconductor package 1a is identical to the structure as shown in FIG. 13. The bottom of at least one of the intermediary terminals 13 of the QFN semiconductor package 1a is not etched away. That is, the intermediary terminal 13 of the QFN semiconductor package 1a protrudes from a bottom surface of the mold cap 30. The circuit board 2″ adapted for the QFN semiconductor package 1a may comprise a core layer 210, a first metal trace 212 disposed on a package assembling side 2a of the circuit board 2, a second metal trace 214 disposed on a bottom side 2b of the circuit board 2, a first solder mask 222 covering the first metal trace 212, a second solder mask 224 covering the second metal trace 214. The first metal trace 212 may be electrically connected the second metal trace 214 by means of the plated through hole 216. The first solder mask 222 has at least openings 222a, 222b and 222c that expose bond pads 212a, 212b and 212c respectively. The bond pads 212a, 212b and 212c correspond to the die attach pad 10, the inner terminal lead 12 and the outer terminal lead 14 respectively. According to this embodiment, no opening is formed in the first solder mask 222 within the area 320 corresponding to the intermediary terminal 13. According to this embodiment, a metal pad 212d is disposed within the area 320 corresponding to the intermediary terminal 13. When assembling, the QFN semiconductor package 1a is mounted on the package assembling side 2a of the circuit board 2′. The die attach pad 10 directly contacts the bond pad 212a. The inner terminal lead 12 directly contacts the bond pad 212b. The outer terminal lead 14 directly contacts the bond pad 212c. The intermediary terminal 13 may directly contact the solder mask 222 and may be supported by the metal pad 212d.

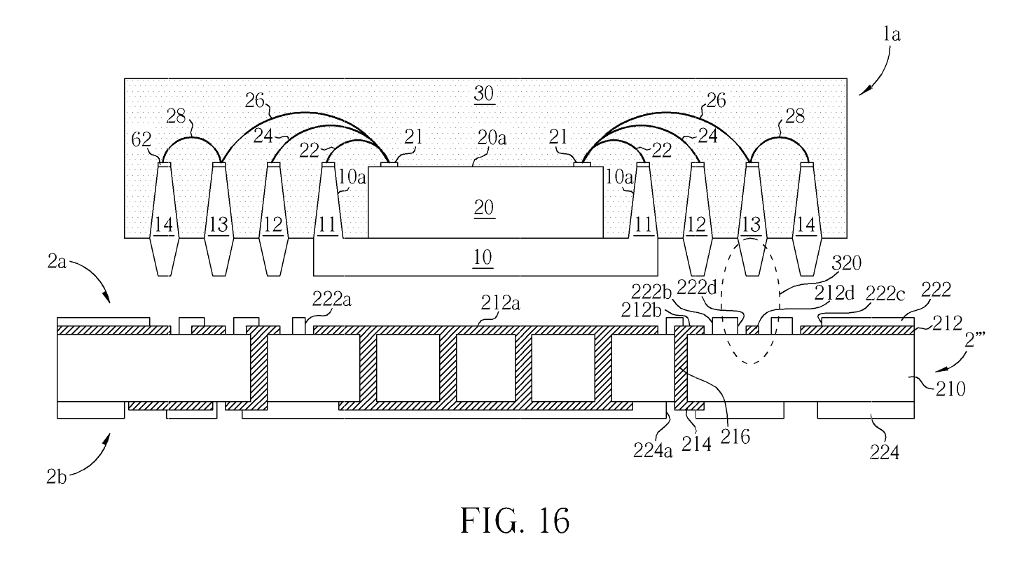

FIG. 16 is a schematic, cross-sectional diagram illustrating a circuit board structure adapted for the novel QFN semiconductor package with intermediary terminals in accordance with still another aspect of this invention. As shown in FIG. 16, the QFN semiconductor package 1a is identical to the structure as shown in FIG. 13. The bottom of at least one of the intermediary terminals 13 of the QFN semiconductor package 1a is not etched away. That is, the intermediary terminal 13 of the QFN semiconductor package 1a protrudes from a bottom surface of the mold cap 30. The circuit board 2′″ adapted for the QFN semiconductor package 1a may comprise a core layer 210, a first metal trace 212 disposed on a package assembling side 2a of the circuit board 2, a second metal trace 214 disposed on a bottom side 2b of the circuit board 2, a first solder mask 222 covering the first metal trace 212, a second solder mask 224 covering the second metal trace 214. The first metal trace 212 may be electrically connected the second metal trace 214 by means of the plated through hole 216. The first solder mask 222 has at least openings 222a, 222b and 222c that expose bond pads 212a, 212b and 212c respectively. The bond pads 212a, 212b and 212c correspond to the die attach pad 10, the inner terminal lead 12 and the outer terminal lead 14 respectively. According to this embodiment, at least an opening 222d that is formed in the first solder mask 222 within the area 320 corresponding to the intermediary terminal 13. According to this embodiment, the opening 222d exposes a dummy, electrically floating metal pad 212d that is disposed within the area 320 corresponding to the intermediary terminal 13. When assembling, the QFN semiconductor package 1a is mounted on the package assembling side 2a of the circuit board 2′. The die attach pad 10 directly contacts the bond pad 212a. The inner terminal lead 12 directly contacts the bond pad 212b. The outer terminal lead 14 directly contacts the bond pad 212c. The intermediary terminal 13 directly contacts the dummy, electrically floating metal pad 212d.

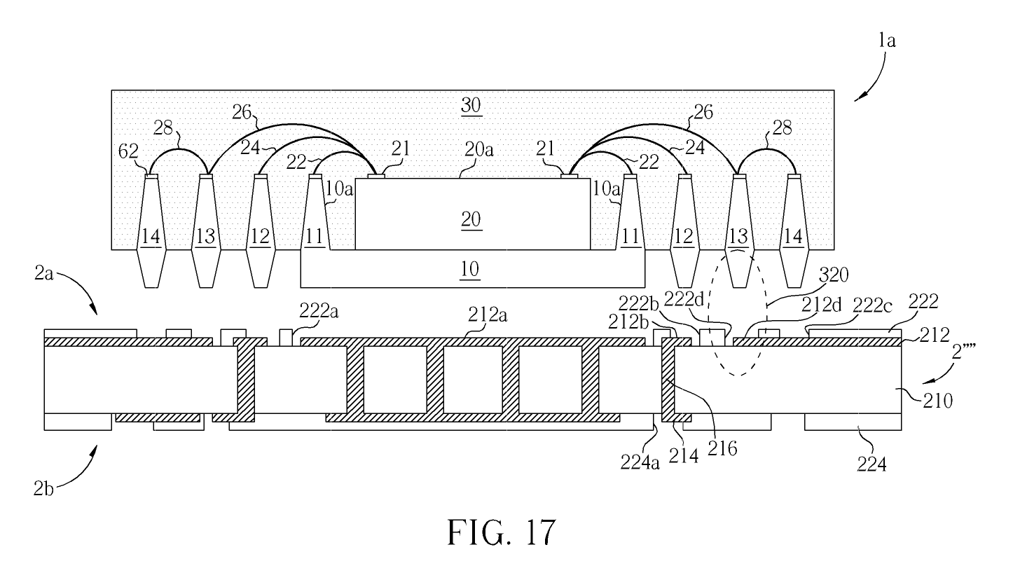

FIG. 17 is a schematic, cross-sectional diagram illustrating a circuit board structure adapted for the novel QFN semiconductor package with intermediary terminals in accordance with still another aspect of this invention. As shown in FIG. 17, the QFN semiconductor package 1a is identical to the structure as shown in FIG. 13. The bottom of at least one of the intermediary terminals 13 of the QFN semiconductor package 1a is not etched away. That is, the intermediary terminal 13 of the QFN semiconductor package 1a protrudes from a bottom surface of the mold cap 30. The circuit board 2″″ adapted for the QFN semiconductor package 1a may comprise a core layer 210, a first metal trace 212 disposed on a package assembling side 2a of the circuit board 2, a second metal trace 214 disposed on a bottom side 2b of the circuit board 2, a first solder mask 222 covering the first metal trace 212, a second solder mask 224 covering the second metal trace 214. The first metal trace 212 may be electrically connected the second metal trace 214 by means of the plated through hole 216. The first solder mask 222 has at least openings 222a, 222b and 222c that expose bond pads 212a, 212b and 212c respectively. The bond pads 212a, 212b and 212c correspond to the die attach pad 10, the inner terminal lead 12 and the outer terminal lead 14 respectively. According to this embodiment, at least an opening 222d that is formed in the first solder mask 222 within the area 320 corresponding to the intermediary terminal 13. According to this embodiment, the opening 222d exposes a metal pad 212d that is disposed within the area 320 corresponding to the intermediary terminal 13. The metal pad 212d is electrically connected to the bond pad 212c. When assembling, the QFN semiconductor package 1a is mounted on the package assembling side 2a of the circuit board 2′. The die attach pad 10 directly contacts the bond pad 212a. The inner terminal lead 12 directly contacts the bond pad 212b. The outer terminal lead 14 directly contacts the bond pad 212c. The intermediary terminal 13 directly contacts the metal pad 212d.

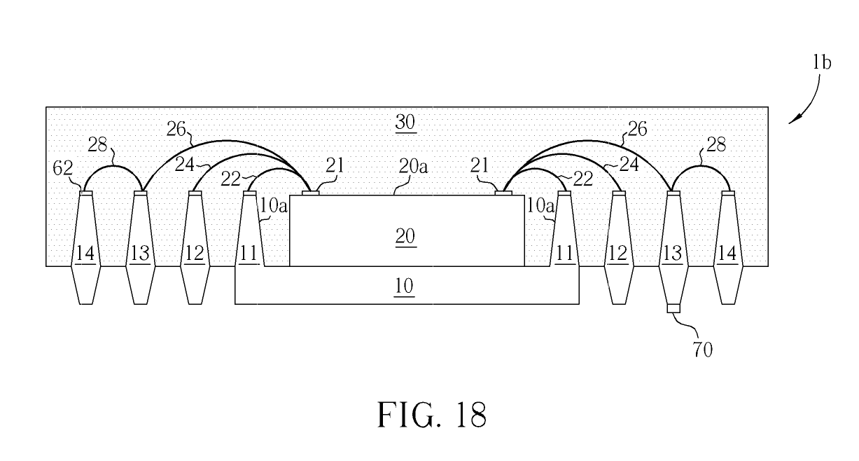

FIG. 18 is a schematic, cross-sectional diagram illustrating a QFN semiconductor package with intermediary terminals in accordance with yet another embodiment of this invention. As shown in FIG. 18, one difference between the QFN semiconductor package 1 of FIG. 1 and the QFN semiconductor package 1b of FIG. 18 is that in FIG. 18 bottom of the intermediary terminal 13 of the QFN semiconductor package 1a is not etched away. That is, the intermediary terminal 13 of the QFN semiconductor package 1a protrudes from a bottom surface of the mold cap 30. Further, a bottom of the intermediary terminal 13 is covered with an electrically non-conductive protection layer 70 such as glue or any suitable insulating materials for avoiding electrically shorting with the printed circuit board. In another embodiment, the protection layer 70 may be replaced with an electrically conductive protection layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuit board adapted for a quad flat non-lead (QFN) semiconductor package, said QFN semiconductor package comprising a die attach pad having a recessed area; a semiconductor die mounted inside said recessed area; at least one inner terminal lead disposed adjacent to the die attach pad; a first wire bonding said inner terminal lead to said semiconductor die; at least one outer terminal lead; at least one intermediary terminal disposed between said inner terminal lead and said outer terminal lead; a second wire bonding said at least one intermediary terminal to said semiconductor die; and a third wire bonding said at least one intermediary terminal to said outer terminal lead, said circuit board comprises:
a core layer having a first side and a second side opposite to said first side;
a first metal trace disposed over said first side of said core layer; and
a first solder mask covering said first metal trace, wherein said QFN semiconductor package is mounted over the first solder mask;
wherein no metal pad of the first metal trace is formed within an area corresponding to said at least one intermediary terminal.

2. The circuit board adapted for a QFN semiconductor package according to claim 1 wherein when assembling, said at least one intermediary terminal directly contacts said first solder mask.

3. The circuit board adapted for a QFN semiconductor package according to claim 1 wherein no opening is formed within said area corresponding to said at least one intermediary terminal.

4. The circuit board adapted for a QFN semiconductor package according to claim 1 wherein said first solder mask comprises an opening within said area corresponding to said at least one intermediary terminal.

5. The circuit board adapted for a QFN semiconductor package according to claim 4 wherein when assembling, said at least one intermediary terminal directly contacts said core layer and is inlaid into said opening.

6. The circuit board adapted for a QFN semiconductor package according to claim 1 wherein said circuit board further comprises a second metal trace disposed over said second side and a second solder mask covering said second metal trace.

7. The circuit board adapted for a QFN semiconductor package according to claim 1 wherein said at least one intermediary terminal protrudes from a bottom surface of a mold cap that encapsulates said semiconductor die, said first and second wires, and upper portions of said inner terminal lead, said at least one intermediary terminal and said outer terminal lead.

8. A circuit board adapted for a quad flat non-lead (QFN) semiconductor package, said QFN semiconductor package comprising a die attach pad having a recessed area; a semiconductor die mounted inside said recessed area; at least one inner terminal lead disposed adjacent to the die attach pad; a first wire bonding said inner terminal lead to said semiconductor die; at least one outer terminal lead; at least one intermediary terminal disposed between said inner terminal lead and said outer terminal lead; a second wire bonding said at least one intermediary terminal to said semiconductor die; and a third wire bonding said at least one intermediary terminal to said outer terminal lead, said circuit board comprises:
a core layer having a first side and a second side opposite to said first side;
a first metal trace disposed over said first side of said core layer;
a first solder mask covering said first metal trace, wherein said QFN semiconductor package is mounted over the first solder mask; and
a metal pad of said first metal trace formed within an area corresponding to said at least one intermediary terminal.

9. The circuit board adapted for a QFN semiconductor package according to claim 8 wherein no opening is formed in said first solder mask within said area corresponding to said at least one intermediary terminal.

10. The circuit board adapted for a QFN semiconductor package according to claim 8 wherein said metal pad is covered by said first solder mask.

11. The circuit board adapted for a QFN semiconductor package according to claim 10 wherein when the QFN semiconductor package is assembled onto the circuit board, said at least one intermediary terminal directly contacts the first solder mask and is supported by said metal pad.

12. The circuit board adapted for a QFN semiconductor package according to claim 8 wherein an opening is provided in said first solder mask within an area corresponding to said at least one intermediary terminal.

13. The circuit board adapted for a QFN semiconductor package according to claim 12 wherein said opening exposes said metal pad.

14. The circuit board adapted for a QFN semiconductor package according to claim 13 wherein said metal pad is a dummy, electrically floating metal pad.

15. The circuit board adapted for a QFN semiconductor package according to claim 13 wherein said metal pad is electrically connected to a bond pad corresponding to said outer terminal lead.

16. The circuit board adapted for a QFN semiconductor package according to claim 8 wherein said circuit board further comprises a second metal trace disposed over said second side and a second solder mask covering said second metal trace.

17. A quad flat non-lead (QFN) semiconductor package, comprising:
a die attach pad having a recessed area;
a semiconductor die mounted inside said recessed area;
at least one inner terminal lead disposed adjacent to the die attach pad;
a first wire bonding said inner terminal lead to said semiconductor die;
at least one outer terminal lead;
at least one intermediary terminal disposed between said inner terminal lead and said outer terminal lead;
a second wire bonding said intermediary terminals to said semiconductor die; and
a third wire bonding said at least one intermediary terminal to said outer terminal lead, wherein said at least one intermediary terminal protrudes from a bottom surface of a mold cap that encapsulates said semiconductor die, said first and second wires, and upper portions of said inner terminal lead, said at least one intermediary terminal and said outer terminal lead.

18. The circuit board adapted for a QFN semiconductor package according to claim 17 wherein a bottom of said at least one intermediary terminal is covered with a non-conductive protection layer.
